(19) United States
(12) Patent Application Publication
(10) Pub. No.: US 2016/0056278 A1
(43) Pub. Date: Feb. 25, 2016

(54) TUNNELING FIELD EFFECT TRANSISTORS (TFETS) WITH UNDOPED DRAIN UNDERLAP WRAP-AROUND REGIONS

(71) Applicant: INTEL CORPORATION, Santa Clara, CA (US)

(72) Inventors: Uygar E. AVCI, Portland, OR (US); Raseong KIM, Hillsboro, OR (US); Ian A. YOUNG, Portland, OR (US)

(73) Assignee: INTEL CORPORATION, Santa Clara, CA (US)

(21) Appl. No.: 14/779,943

(22) PCT Filed: Jun. 27, 2013
(86) PCT No.: PCT/US2013/048351

§ 371 Date: Sep. 24, 2015

(51) Int. Cl. H01L 29/78; H01L 29/08; H01L 29/66; H01L 29/205; H01L 29/20

(52) U.S. Cl. CPC H01L 29/785; H01L 29/205; H01L 29/20; H01L 29/66977; H01L 29/0847

(57) ABSTRACT

Tunneling field effect transistors (TFETs) with undoped drain underlap wrap-around regions are described. For example, a tunneling field effect transistor (TFET) includes a homojunction active region formed above a substrate. The homojunction active region includes a doped source region, an undoped channel region, a wrapped-around region, and a doped drain region. A gate electrode and gate dielectric layer are formed on the undoped channel region, between the source and wrapped-around regions.

### TECHNICAL FIELD

Embodiments of the invention are in the field of semiconductor devices and, in particular, tunneling field effect transistors (TFETs) with undoped drain underlap wrap-around regions.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, leading to the fabrication of products with increased capacity. The drive for ever-more capacity, however, is not without issue. The necessity to optimize the performance of each device becomes increasingly significant.

In the manufacture of integrated circuit devices, a metal oxide semiconductor field effect transistor's (MOSFET) sub-threshold slope has a theoretical lower limit of kT/q (60 mV/dec at room temperature) with k being Boltzmann's constant, T being absolute temperature, and q being the magnitude of electron charge on an electron. For low active-power, it is very favorable to operate at lower supply voltages because of active power's strong dependence on supply voltage (e.g., a dependency of approximately Capacitance (C)*Voltage (V)²). However, due to limited (kT/q) rate of increase of current from off-current to on-current, when MOSFET is operated at low supply-voltages, the on-current would be significantly lower because it may be operating close to its threshold-voltage. A different type of transistor—tunneling FET (TFET) has been shown to achieve sharper turn-on behavior (steeper subthreshold-slope) than MOSFET. This enables higher on-currents than MOSFET at low supply-voltages, as shown in FIG. 1. FIG. 1 illustrates drain current (Id) versus gate voltage (Vg) for a low power MOSFET and an InAs TFET for a gate length of 20 nanometers (nm). A heterojunction TFET, which uses a combination of two semiconductor materials to enable higher tunneling current, enables better TFET characteristics as illustrated in FIG. 2. FIG. 2 also illustrates a low power MOSFET and a homojunction InAs TFET for a gate length of 15 nm, a gate oxide thickness of 0.8 nm, a drain to source voltage of 0.3 volts, and an off current of 1 nA/um.

However, TFET devices require a long drain underlap—an undoped region between gate edge and doped drain region, to keep its steep sub-threshold slope and low off-current leakage at short gate lengths. FIG. 3 shows an InAs TFET curve 302 with drain underlap and InAs TFET curve 306 having symmetric source/drain spacers without a drain underlap. Without drain underlap, the leakage current is high and the subthreshold slope is not steep for curve 306. When drain underlap is introduced, leakage reduces and a sub-threshold slope steeper than 60 mV/dec can be achieved. The curve 304 shows the device characteristics for a low power MOSFET.

FIG. 4 shows cross-sectional sketches for a TFET device 400 with drain underlap and a TFET device 450 without drain underlap. Although the TFET device 400 with a drain underlap achieves better device characteristics including lower leakage and steeper subthreshold-slope, it requires a longer device, costing extra area for the transistor layout. Also, a longer drain underlap region 410 will likely require a different spacer processing, adding to process complexity and cost.

### BRIEF DESCRIPTION OF THE DRAWINGS

FIG. 1 illustrates turn-on behavior for a TFET device versus a low-power MOSFET device for a conventional approach.

FIG. 2 illustrates turn-on behavior for homojunction and hetero-junction TFET devices versus a low-power MOSFET device for a conventional approach.

FIG. 3 illustrates turn-on behavior for TFET devices with drain underlap, no drain underlap, and for a low-power MOSFET device for a conventional approach.

FIG. 4 illustrates cross-sections of TFET devices with and without drain underlap for a conventional approach.

FIG. 5 illustrates a tunneling path of an electron at a source side of a heterojunction TFET device with a drain underlap.

FIG. 6a illustrates a top down view 600 of a multi-gate device architecture, in accordance with an embodiment of the present invention.

FIG. 6b illustrates a cross-sectional view 650 through a cross-section 610 of the active region 620 of the multi-gate device architecture of FIG. 6a, in accordance with an embodiment of the present invention.

FIG. 7a illustrates a top down view 700 of a multi-gate device architecture during a lithography operation, in accordance with an embodiment of the present invention.

FIG. 7b illustrates a cross-sectional view 750 through a cross-section 710 of the active region 720 of the multi-gate device architecture of FIG. 7a, in accordance with an embodiment of the present invention.

FIG. 8a illustrates a top down view 800 of a multi-gate device architecture, in accordance with an embodiment of the present invention.

FIG. 8b illustrates a cross-sectional view 850 through a cross-section 810 of an active region of the multi-gate device architecture of FIG. 8a, in accordance with an embodiment of the present invention.

FIG. 9a illustrates a top down view 900 of a multi-gate device architecture, in accordance with an embodiment of the present invention.

FIG. 9b illustrates a cross-sectional view 950 through a cross-section 910 of the active region 920 of the multi-gate device architecture of FIG. 9a, in accordance with an embodiment of the present invention.

FIG. 10a illustrates a top down view 1000 of a multi-gate device architecture, in accordance with an embodiment of the present invention.

FIG. 10b illustrates a cross-sectional view 1050 through a cross-section 1010 of an active region 1020 of the multi-gate device architecture of FIG. 10a, in accordance with an embodiment of the present invention.

FIG. 11a illustrates a top down view 1100 of a multi-gate device architecture with wrapped-around and symmetric spacers, in accordance with an embodiment of the present invention.

FIG. 11b illustrates a cross-sectional view 1150 through a cross-section 1110 of the active region 1120 of the multi-gate device architecture of FIG. 11a, in accordance with an embodiment of the present invention.

FIG. 12a illustrates a top down view 1200 of a multi-gate device architecture with wrapped-around drain underlap having symmetric spacers, in accordance with an embodiment of the present invention.

FIG. 12b illustrates a cross-sectional view 1250 through a cross-section 1210 of the active region 1220 of the multi-gate device architecture of FIG. 12a, in accordance with an embodiment of the present invention.

FIG. 13 illustrates a cross-sectional view 1300 through a cross-section 1212 of the active region 1220 of the multi-gate device architecture of FIG. 12b, in accordance with an embodiment of the present invention.

FIG. 14 illustrates a cross-sectional view 1400 through a cross-section of an active region of a conventional long TFET.

FIG. 15 illustrates a device cross-section for the wrapped-around TFET, in accordance with an embodiment of the present invention.

FIG. 16 illustrates a device cross-section for the conventional long horizontal TFET.

FIGS. 17 and 18 illustrate potential profiles for the conventional long horizontal TFET and the wrapped-around TFET, in accordance with an embodiment of the present invention.

FIG. 19 illustrates a computing device in accordance with one implementation of the invention.

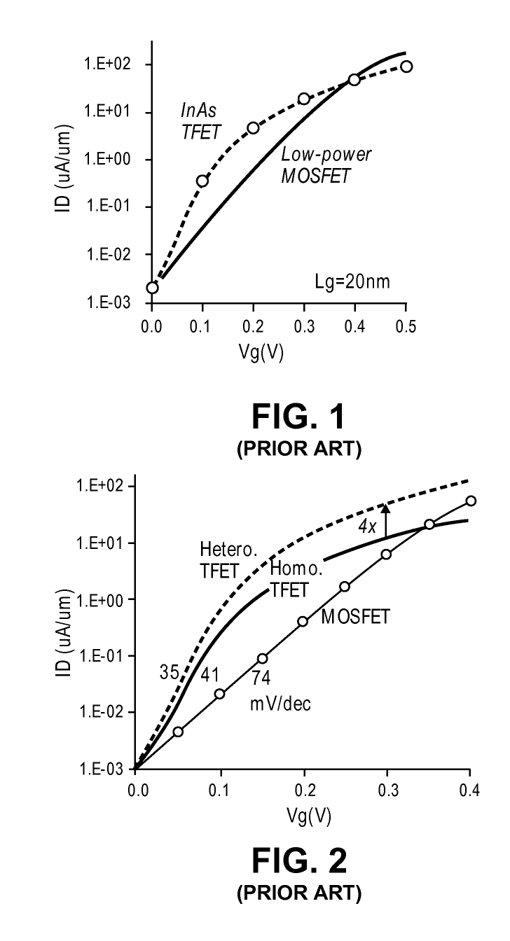

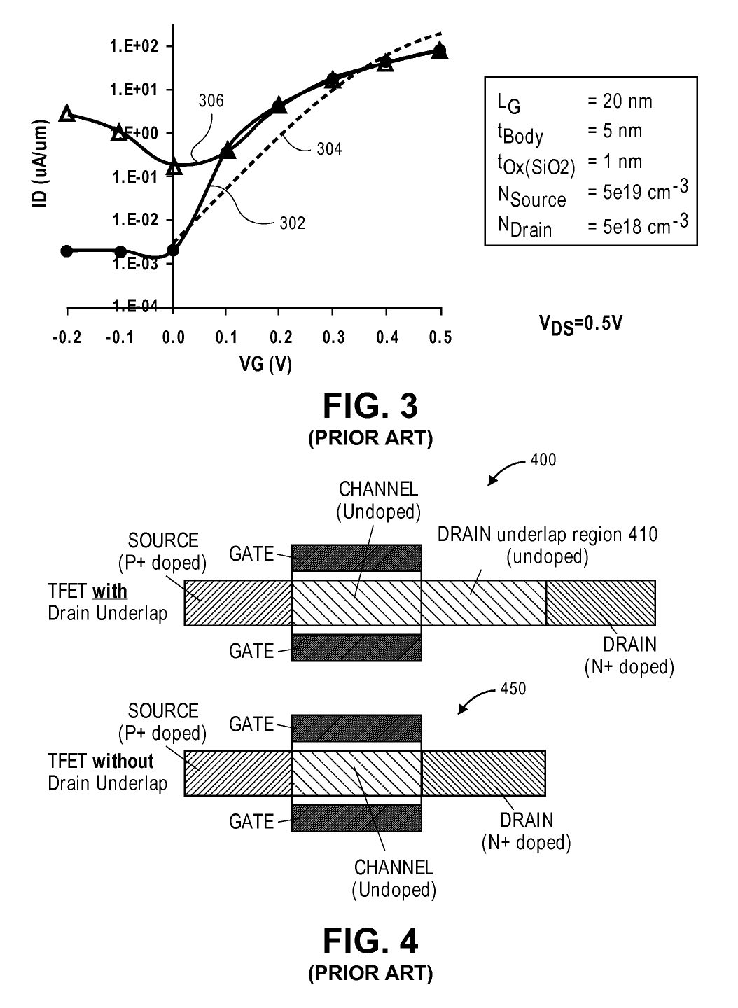

### DESCRIPTION OF THE EMBODIMENTS

Tunneling field effect transistors (TFETs) with undoped drain underlap wrap-around regions are described. In the following description, numerous specific details are set forth, such as specific integration and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

In one embodiment, TFETs are used to achieve steeper sub-threshold slope (SS) and lower leakage versus a corresponding metal oxide semiconductor field effect transistor (MOSFET) with a thermal limit of approximately 60 mV/decade. Generally, embodiments described herein may be suitable for high performance or scaled transistors for logic devices having low power applications.

To provide a background context, a conventional TFET design requires an undoped region between the gate edge and the n+ doped drain region, called the drain underlap region as illustrated in FIG. 4. This prevents degradation of a TFET device's steep sub-threshold slope and keeps leakage current low. The leakage and sub-threshold degradation is due to ambipolar leakage and a short-channel effect. Ambipolar leakage is caused by band-to-band-tunneling between the channel and drain region. A short channel effect includes tunneling from source to either channel or drain due to drain effect on channel potential and short source-to-drain distance.

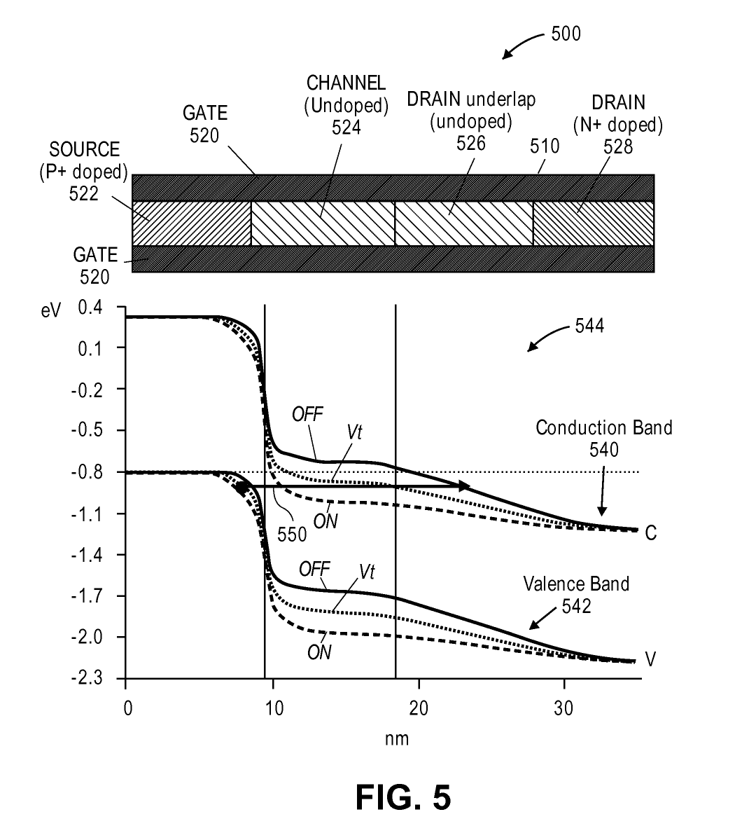

FIG. 5 illustrates a tunneling path of an electron at a source side of a heterojunction TFET device with a drain underlap region. The TFET device 500 includes a gate 520, a source region 522 (e.g., p+ doped), a channel 524 (e.g., undoped channel), a drain underlap region 526 (e.g., undoped), and a drain region 528 (e.g., n+ doped). An energy band structure 544 for the TFET device is shown below the TFET device. The energy band structure 544 includes a conduction band 540 and a valence band 542. Electrons within the conduction band are mobile charge carriers in solid state devices. The energy band structure shows electron energy in units of eV on a vertical axis and a position within the TFET device in units of nanometers on a horizontal axis.

Leakage is dominated by a tunneling distance from the source to a point in the drain of the TFET device. If this distance is longer, then leakage will be lower. The shortest path illustrated by arrow 550 to the other side of the bandgap together with the height of barrier semi-classically explains how large the tunneling current will be. Thus, it is desirable to keep this tunneling distance longer during an off condition and shorter during an on condition of the TFET device.

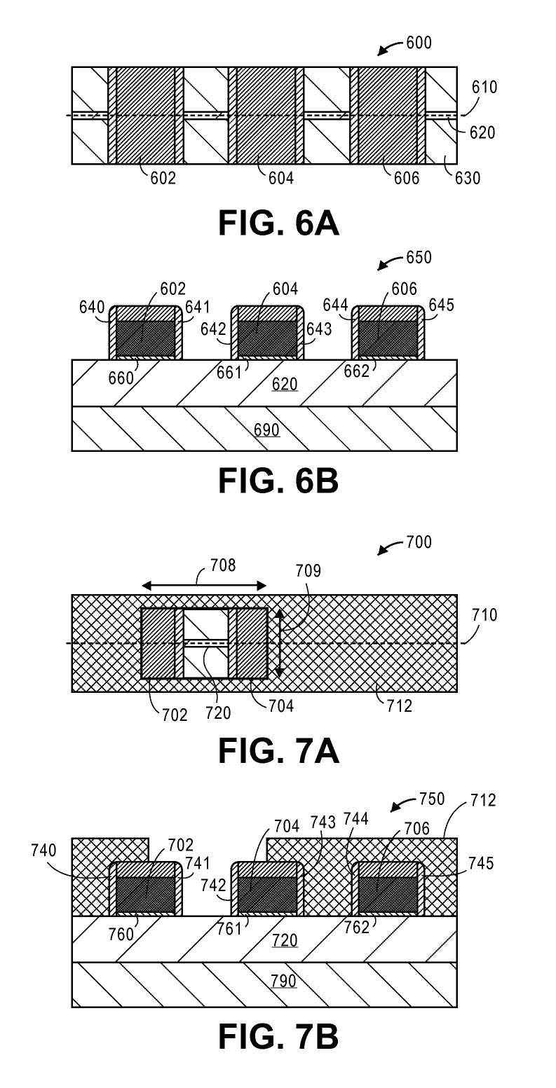

Generally, FIG. 6a illustrates a top down view 600 of a multi-gate device architecture, in accordance with an embodiment of the present invention. In one embodiment, the device architecture (e.g., tri-gate, FinFET) includes gate electrodes 602, 604, 606, an active region or fin 620, and isolation region 630. Generally, FIG. 6b illustrates a cross-sectional view 650 through a cross-section 610 of the active region 620 of the multi-gate device architecture of FIG. 6a, in accordance with an embodiment of the present invention. The device architecture includes the gates 602, 604, 606, the dielectric layers 660-662, gate spacers 640-645, the active region 620, and a substrate 690. This design architecture includes a wrapped-around drain underlap design as illustrated in FIGS. 6A-13 and 15 in order to achieve TFET devices without thick gate spacers or a longer device layout such as a horizontal drain underlap design, which is illustrated in FIG. 14.

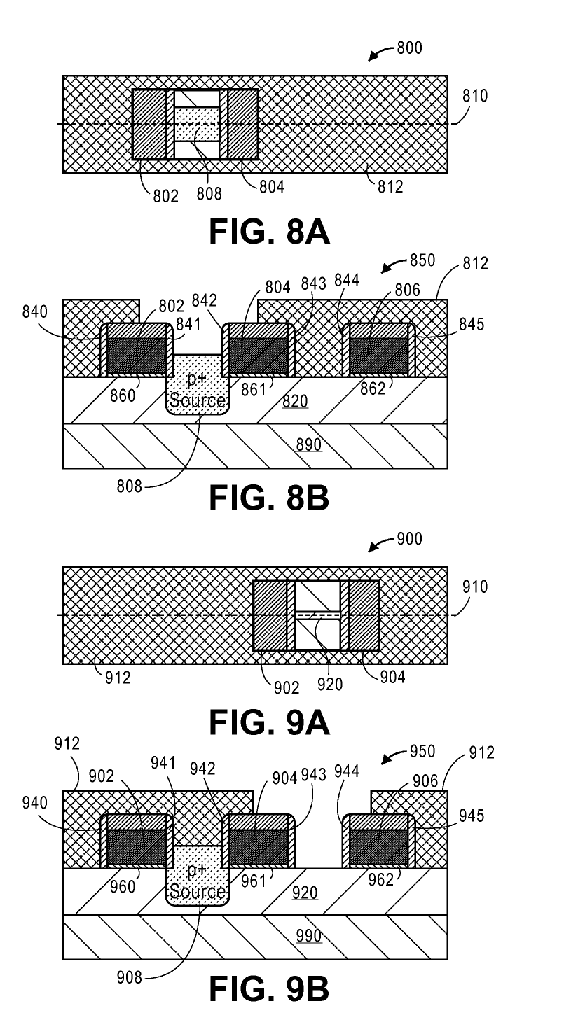

Generally, FIG. 7a illustrates a top down view 700 of a multi-gate device architecture during a lithography operation, in accordance with an embodiment of the present invention. In one embodiment, the device architecture (e.g., tri-gate, FinFET) includes a blocking layer 712 with an opening that exposes gate electrodes 702, 704, and an active region 720. The opening has a length 708 approximately equal to a polysilicon pitch and a width 709. Generally, FIG. 7b illustrates a cross-sectional view 750 through a cross-section 710 of the active region 720 of the multi-gate device architecture of FIG. 7a, in accordance with an embodiment of the present invention. The device architecture includes the gate electrodes 702, 704, 706 and respective gate spacers 740-745 and gate dielectric layers 760-762. The device architecture also includes the blocking layer 712, the active region 720, and the substrate 790. The blocking layer 712 provides an opening to the active region in a source region. The exposed active region is then either implanted with p+ doping or etched and a p+ in-situ doped source region is grown as illustrated in FIGS. 8a and 8b.

Generally, FIG. 8a illustrates a top down view 800 of a multi-gate device architecture, in accordance with an embodiment of the present invention. In one embodiment, the device architecture (e.g., tri-gate, finFET) includes a blocking layer 812 with an opening that exposes gate electrodes 802 and 804 and a source region 808 (p+ source region). Generally, FIG. 8b illustrates a cross-sectional view 850 through a cross-section 810 of an active region of the multi-gate device architecture of FIG. 8a, in accordance with an embodiment of the present invention. The device architecture includes the gate electrodes 802, 804, 806 and respective gate spacers 840-845 and gate oxide layers 860-862. The device architecture also includes the blocking layer 812, the active region 820, and the substrate 890. The p+ source region is formed in the active region 820 with implantation or partially in the active region with an etch and in-situ doped source growth. After a photoresist and block layer 812 (or hard mask) are removed, then a new lithography operation is performed to open drain regions as illustrated in FIGS. 9a and 9b.

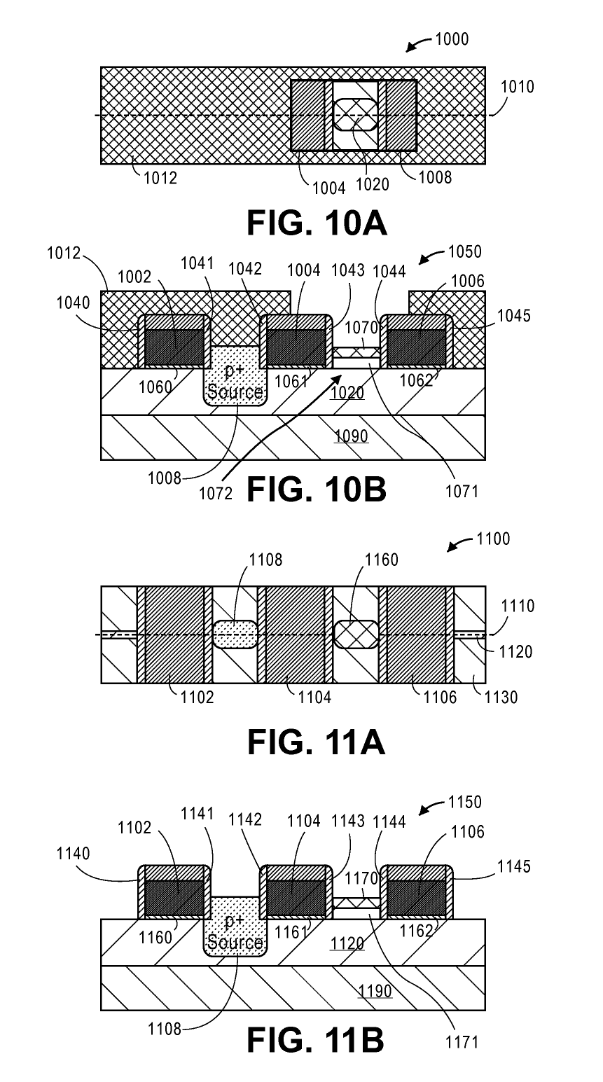

Generally, FIG. 9a illustrates a top down view 900 of a multi-gate device architecture, in accordance with an embodiment of the present invention. In one embodiment, the device architecture (e.g., tri-gate, finFET) includes a blocking layer 912 with an opening that exposes gate electrodes 902 and 904 and an active region 920 for forming a drain region. Generally, FIG. 9b illustrates a cross-sectional view 950 through a cross-section 910 of the active region 920 of the multi-gate device architecture of FIG. 9a, in accordance with an embodiment of the present invention. The device architecture includes the gate electrodes 902, 904, 906 and respective gate spacers 940-945 and gate dielectric layers 960-962. The device architecture also includes the blocking layer 912, the active region 920, and the substrate 990. A drain region is formed on the undoped active region 920 by growing a thin layer of additional undoped material and then growing in-situ n-doped material or implanting the region with a low dose and low energy n-type doping as illustrated in FIGS. 10a and 10b.

Generally, FIG. 10a illustrates a top down view 1000 of a multi-gate device architecture, in accordance with an embodiment of the present invention. In one embodiment, the device architecture (e.g., tri-gate, finFET) includes a blocking layer 1012 with an opening that exposes gates 1004 and 1008 and an active region 1020 for forming a drain region with n+ doping. Generally, FIG. 10b illustrates a cross-sectional view 1050 through a cross-section 1010 of an active region of the multi-gate device architecture of FIG. 10a, in accordance with an embodiment of the present invention. The device architecture includes the gate electrodes 1002, 1004, 1006 and respective gate spacers 1040-1045 and gate oxide layers 1060-1062. The device architecture also includes the blocking layer 1012, the active region 1020, and the substrate 1090. A drain region 1072 is formed on the undoped active region 1020 by growing a thin layer 1071 of additional undoped material and then growing in-situ n-doped material 1070 or implanting the region with a low dose and low energy n-type doping. After the photoresist and block layer 1012 (or hard mask) are removed, then a TFET with wrapped-around drain underlap having symmetric spacers is formed as illustrated in FIGS. 11a and 11b.

Generally, FIG. 11a illustrates a top down view 1100 of a multi-gate device architecture with wrapped-around drain underlap and symmetric spacers, in accordance with an embodiment of the present invention. In one embodiment, the device architecture (e.g., tri-gate, FinFET) includes gates 1102, 1104, and 1106 and an active region 1120 (e.g., fin or body) for forming a source region 1108 (e.g., p+ source region) and a drain region 1160 (e.g., n+ drain region). Generally, FIG. 11b illustrates a cross-sectional view 1150 through a cross-section 1110 of the active region 1120 of the multi-gate device architecture of FIG. 11a, in accordance with an embodiment of the present invention. The device architecture includes the gate electrodes 1102, 1104, 1106 and respective gate spacers 1140-1145 and gate dielectric layers 1160-1162 (e.g., gate oxide layers). The device architecture also includes the active region 1120 and the substrate 1190. A drain region is formed on the undoped active region 1120 by growing a thin layer 1171 of additional undoped material and then growing in-situ n-doped material 1170 or implanting the region including layer 1171 with a low dose and low energy n-type doping. A source region 1108 (e.g., p+ source region) is also formed on the undoped active region 1120. A similar process approach illustrated in FIGS. 6a-11b can be applied for a heterojunction TFET device design to provide enhanced TFET performance.

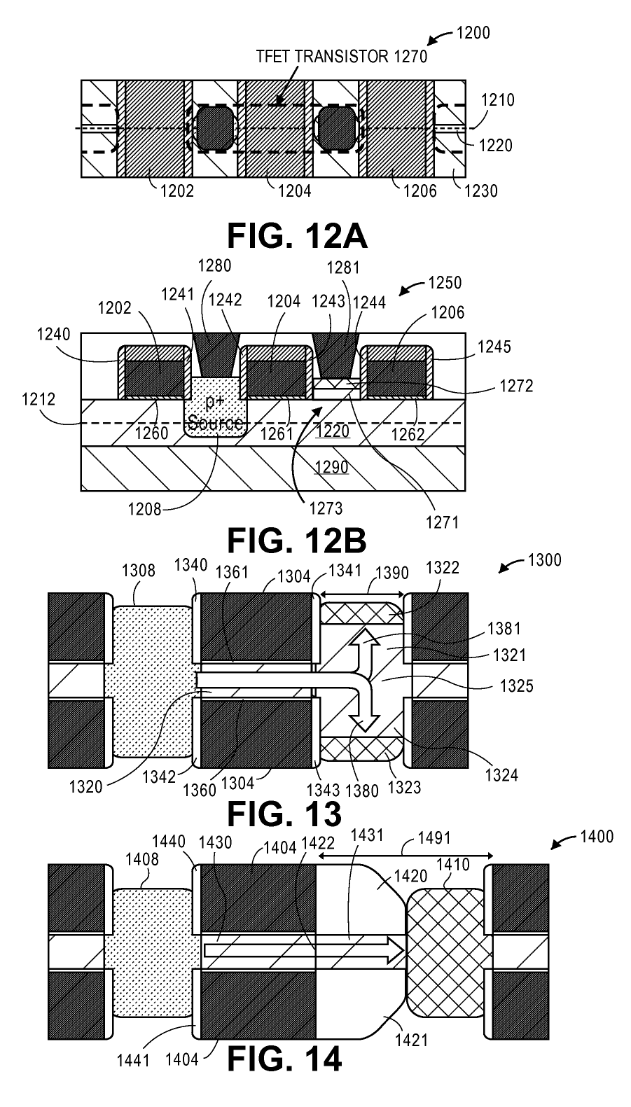

Generally, FIG. 12a illustrates a top down view 1200 of a multi-gate device architecture with wrapped-around drain underlap having symmetric spacers, in accordance with an embodiment of the present invention. In one embodiment, the device architecture (e.g., tri-gate, finFET) includes gate electrodes 1202, 1204, and 1206 and an active region 1220 for forming a source region (e.g., p+ source region) and a drain region (e.g., n+ drain region) for a small size TFET transistor 1270. Generally, FIG. 12b illustrates a cross-sectional view 1250 through a cross-section 1210 of the active region 1220 of the multi-gate device architecture of FIG. 12a, in accordance with an embodiment of the present invention. The device architecture includes the gate electrodes 1202, 1204, 1206 and respective symmetric gate spacers 1240-1245 and gate dielectric layers 1260-1262. The device architecture also includes the active region 1220 (e.g., undoped InAs), the substrate 1290, a source region 1208 with p+ doping (e.g., GaSb) and a drain region 1273. The drain region 1273 is formed on the undoped active region 1220 by growing a thin layer 1271 of additional undoped material (e.g., InAs) and then growing in-situ n-doped material 1272 (e.g., n-type InAs) or implanting the region including layer 1271 with a low dose and low energy n-type doping. FIGS. 12a and 12b illustrate different views of an n-type TFET using GaSb in the source region and InAs in the active region including channel regions under the gate regions and also the drain region 1273. In one embodiment, a p-type TFET can be designed with Si, Ge, Sn or any alloy of these materials in the source region and Si, Ge, Sn or any alloy of these materials in the active region including channel regions under the gate regions and also drain regions. In an embodiment, a TFET can be designed with In, Ga, Al, As, Sb, P, N or any alloy of these materials in the source region and In, Ga, Al, As, Sb, P, N or any alloy of these materials in the active region including channel regions under the gate regions and also drain regions. Including contacts (e.g., a source contact 1280 and a drain contact 1281), the TFET device can be designed as small as a counterpart MOSFET device.

Generally, FIG. 13 illustrates a cross-sectional view 1300 through a cross-section 1212 of the active region 1220 of the multi-gate device architecture of FIG. 12b, in accordance with an embodiment of the present invention. The device architecture includes the gate electrode 1304 and respective symmetric gate spacers 1340-1343 and gate oxide layers 1360-1361. The device architecture also includes the active region 1320 (e.g., undoped InAs), a source region 1308 with p+ doping (e.g., GaSb) and a drain region 1325. The drain region 1325 is formed on the undoped active region 1320 by growing a thin layer 1321, 1324 of additional undoped material (e.g., InAs) and then growing in-situ n-doped material 1322, 1323 (e.g., n-type InAs) or implanting the region including layer 1321, 1324 with a low dose and low energy n-type doping. Arrows 1380 and 1381 indicate paths of electrons from the source region to the drain region.

Generally, FIG. 14 illustrates a cross-sectional view 1400 through a cross-section of an active region of a conventional multi-gate device architecture. The device architecture includes the gate electrode 1404 and respective asymmetric gate spacers 1420, 1421, 1440, 1441 and gate dielectric layers. The device architecture also includes the active region 1430 (e.g., undoped InAs), a source region 1408 with p+ doping (e.g., GaSb), drain underlap region 1431, and a drain region 1410 (e.g., n-type InAs). FIG. 14 illustrates the conventional long horizontal drain underlap TFET while FIG. 13 illustrates a wrapped-around drain underlap TFET. Arrow 1422 indicates a path of an electron from the source region to the drain region.

Although the wrapped-around TFET of FIG. 13 has a shorter device length in comparison to the TFET of FIG. 14, the wrapped-around TFET still has good electrostatics to keep leakage current low.

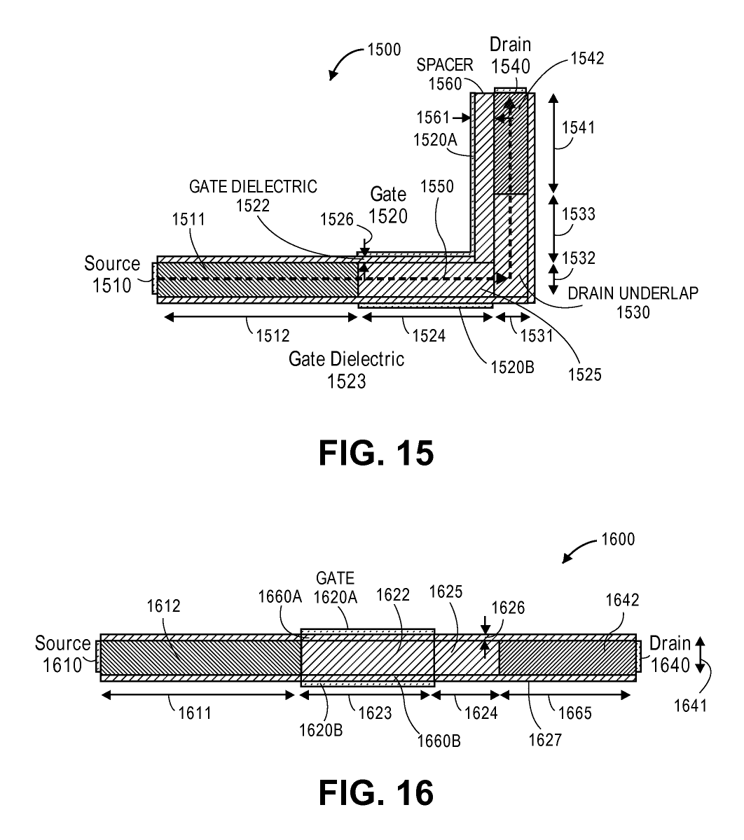

FIGS. 15 and 16 illustrate device cross-sections for the wrapped-around TFET 1500 and the conventional long horizontal TFET, respectively. Generally, FIG. 15 illustrates a device cross-section for the wrapped-around TFET, in accordance with an embodiment of the present invention. The wrapped-around TFET 1500 includes gate electrodes 1520a, 1520b, a gate spacer 1560 and gate dielectric layers 1522 and 1523. An additional symmetric gate spacer and additional drain portion are not shown in FIG. 15 with the additional symmetric gate spacer being symmetric with respect to the spacer 1560 and the additional drain portion being symmetric with respect to a drain electrode 1540 and a drain region 1542. The TFET device includes an active region 1525 or body (e.g., undoped InAs), a source electrode 1510, a source region 1511 with p+ doping (e.g., GaSb), the drain electrode 1540 with the drain region 1542, and a drain underlap region 1530. In one embodiment, the active region 1525 or body has a width of 5 nm as illustrated with double arrows 1531 and 1532. The source has a length 1512 of 30 nm, a channel of the active region has a length 1524 of 20 nm, a drain underlap has a first length 1532 of 5 nm and a second length 1533 of 10 nm, and a drain region has a length 1541 of 15 nm. The gate dielectric layers may have a thickness 1526 of approximately 1 nm. A spacer 1560 has a thickness 1561 of approximately 3 nm. The first and second lengths 1532 and 1533 of the drain underlap 1530 are approximately perpendicular to a device length in order to only contribute a width 1531 of the drain underlap 1530 in a direction of device length but yet provide a length 1532 and 1533 for improved leakage characteristics.

Generally, FIG. 16 illustrates a device cross-section for the conventional long horizontal TFET. The conventional long horizontal TFET 1600 corresponds to the TFET 1400 of FIG. 14. The TFET 1600 includes gate electrodes 1620a, 1620b, gate spacers 1626 and 1627, and gate oxide layers 1660a and 1660b. The TFET device also includes an active region 1622 or body (e.g., undoped InAs), a source electrode 1610, a source region 1612 with p+ doping (e.g., GaSb), a drain electrode 1640 with a drain region 1642 with n+ doping, and a drain underlap region 1625. The active region 1622 or body has a width of 5 nm as illustrated with double arrows 1641. The drain has a length 1665 of 20 nm, a channel has a length 1623 of 20 nm, a drain underlap has a length 1624 of 10 nm, and a source region has a length 1611 of 30 nm.

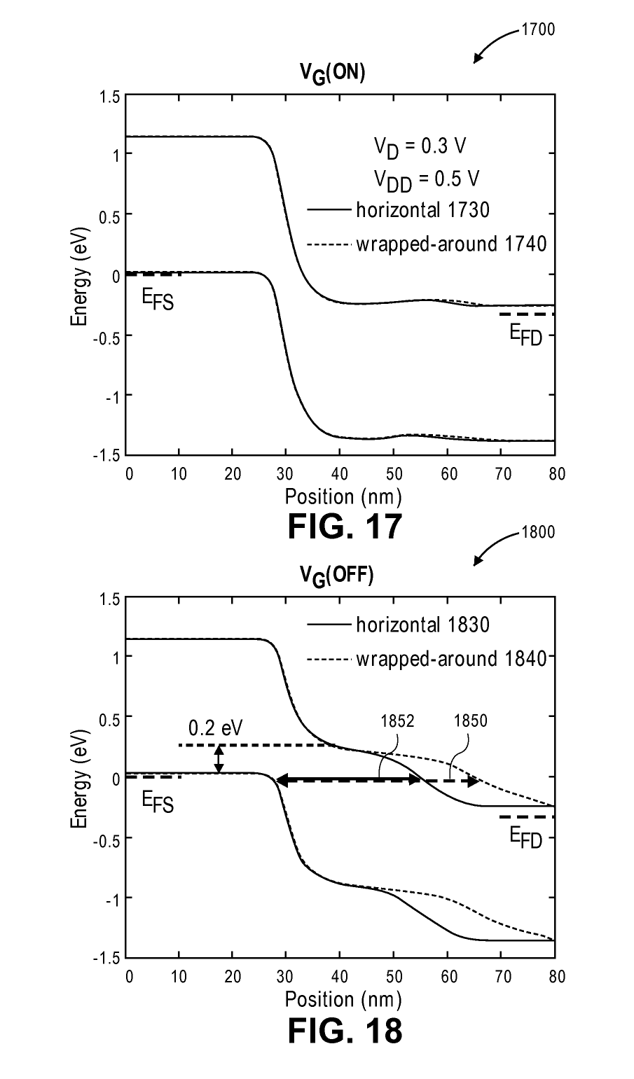

FIGS. 17 and 18 illustrate potential profiles for the conventional long horizontal TFET and the wrapped-around TFET, in accordance with an embodiment of the present invention. FIG. 17 illustrates potential profiles for the conventional long horizontal TFET and the wrapped-around TFET for when the gates of the TFET devices are ON, in accordance with an embodiment of the present invention. The graph 1700 shows energy (eV) versus position within the respective TFET device. The conduction band (upper band) and valence band (lower band) of the conventional long horizontal TFET 1730 are nearly identical to the conduction band (upper band) and valence band (lower band) of the wrapped-around TFET 1740 with the gate voltage bias being sufficient to turn ON the devices.

FIG. 18 illustrates potential profiles for the conventional long horizontal TFET and the wrapped-around TFET for when the TFET devices are OFF, in accordance with an embodiment of the present invention. The graph 1800 shows energy (eV) versus position within the respective TFET device. The conduction band (upper band) and valence band (lower band) of the conventional long horizontal TFET 1830 are nearly identical to the conduction band (upper band) and valence band (lower band) of the wrapped-around TFET 1840 for a position (nm) of zero to 40. The conduction and valence bands of these devices diverge from a position of approximately 40 to 80 with the devices being biased for OFF condition. A tunneling path 1850 of the wrapped-around TFET of an electron from the valence to the conduction band is significantly longer than a tunneling path 1852 of the conventional long horizontal TFET. The tunneling path is correlated to the leakage current, thus the wrapped-around TFET yields lower leakage currents.

Thus, the wrapped-around TFET has a shorter device length for smaller area and cost and no complex spacer process in comparison to the conventional long horizontal TFET. The wrapped-around TFET also has a better controlled potential profile yielding a lower OFF condition tunneling currents and thus a TFET with lower leakage in comparison to the conventional long horizontal TFET.

In the above described embodiments, whether formed on virtual substrate layers or on bulk substrates, an underlying substrate used for TFET device manufacture may be composed of a semiconductor material that can withstand a manufacturing process. In an embodiment, the substrate is a bulk substrate, such as a P-type silicon substrate as is commonly used in the semiconductor industry. In an embodiment, substrate is composed of a crystalline silicon, silicon/germanium or germanium layer doped with a charge carrier, such as but not limited to phosphorus, arsenic, boron or a combination thereof. In another embodiment, the substrate is composed of an epitaxial layer grown atop a distinct crystalline substrate, e.g. a silicon epitaxial layer grown atop a boron-doped bulk silicon mono-crystalline substrate.

The substrate may instead include an insulating layer formed in between a bulk crystal substrate and an epitaxial layer to form, for example, a silicon-on-insulator substrate. In an embodiment, the insulating layer is composed of a material such as, but not limited to, silicon dioxide, silicon nitride, silicon oxy-nitride or a high-k dielectric layer. The substrate may alternatively be composed of a group III-V material. In an embodiment, the substrate is composed of a III-V material such as, but not limited to, gallium nitride, gallium phosphide, gallium arsenide, indium phosphide, indium antimonide, indium gallium arsenide, aluminum gallium arsenide, indium gallium phosphide, or a combination thereof. In another embodiment, the substrate is composed of a III-V material and charge-carrier dopant impurity atoms such as, but not limited to, carbon, silicon, germanium, oxygen, sulfur, selenium or tellurium.

In the above embodiments, TFET devices include source drain regions that may be doped with charge carrier impurity atoms. In an embodiment, the group IV material source and/or drain regions include N-type dopants such as, but not limited to phosphorous or arsenic. In another embodiment, the group IV material source and/or drain regions include P-type dopants such as, but not limited to boron.

In the above embodiments, although not always shown, it is to be understood that the TFETs include gate stacks with a gate dielectric layer and a gate electrode layer. In an embodiment, the gate electrode of gate electrode stack is composed of a metal gate and the gate dielectric layer is composed of a high-K material. For example, in one embodiment, the gate dielectric layer is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, aluminium oxide, lead scandium tantalum oxide, lead zinc niobate, or a combination thereof. Furthermore, a portion of gate dielectric layer may include a layer of native oxide formed from the top few layers of the corresponding channel region. In an embodiment, the gate dielectric layer is composed of a top high-k portion and a lower portion composed of an oxide of a semiconductor material. In one embodiment, the gate dielectric layer is composed of a top portion of hafnium oxide and a bottom portion of silicon dioxide or silicon oxy-nitride.

In an embodiment, the gate electrode is composed of a metal layer such as, but not limited to, metal nitrides, metal carbides, metal silicides, metal aluminides, hafnium, zirconium, titanium, tantalum, aluminum, ruthenium, palladium, platinum, cobalt, nickel or conductive metal oxides. In a specific embodiment, the gate electrode is composed of a non-workfunction-setting fill material formed above a metal workfunction-setting layer. In an embodiment, the gate electrode is composed of a P-type or N-type material. The gate electrode stack may also include dielectric spacers.

The TFET semiconductor devices described above cover both planar and non-planar devices, including gate-all-around devices. Thus, more generally, the semiconductor devices may be a semiconductor device incorporating a gate, a channel region and a pair of source/drain regions. In an embodiment, semiconductor device is one such as, but not limited to, a MOS-FET. In one embodiment, semiconductor device is a planar or three-dimensional MOS-FET and is an isolated device or is one device in a plurality of nested devices. As will be appreciated for a typical integrated circuit, both N- and P-channel transistors may be fabricated on a single substrate to form a CMOS integrated circuit. Furthermore, additional interconnect wiring may be fabricated in order to integrate such devices into an integrated circuit.

Generally, one or more embodiments described herein are targeted at tunneling field effect transistors (TFETs) with undoped drain underlap wrap-around regions. Group IV or III-V active layers for such devices may be formed by techniques such as, but not limited to, chemical vapor deposition (CVD) or molecular beam epitaxy (MBE), or other like processes.

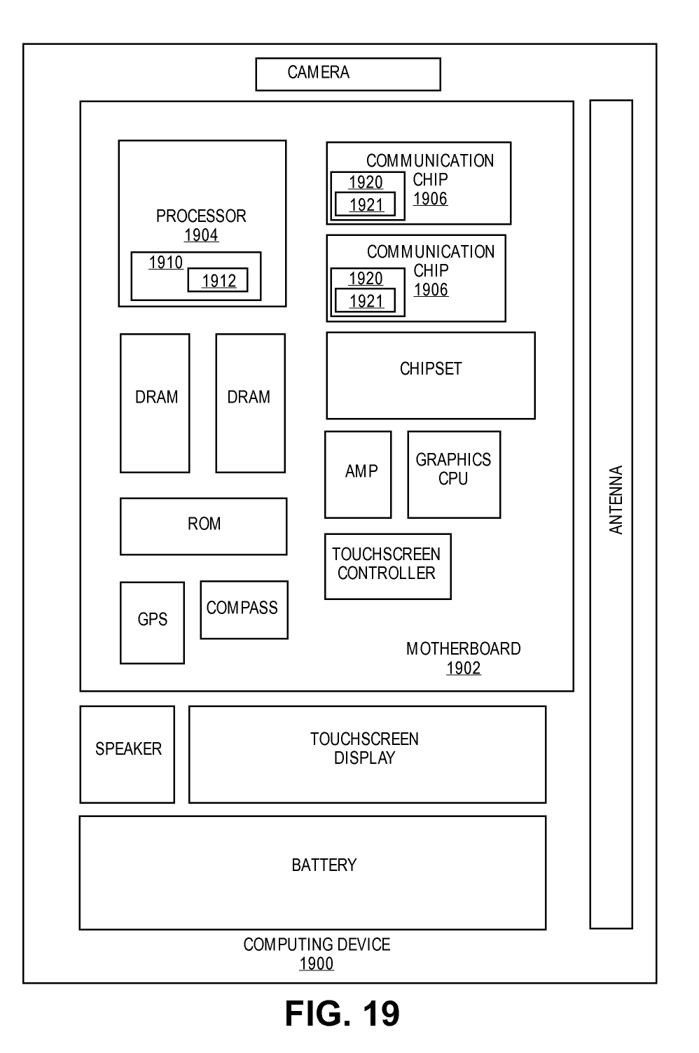

FIG. 19 illustrates a computing device 1900 in accordance with one implementation of the invention. The computing device 1900 houses a board 1902. The board 1902 may include a number of components, including but not limited to a processor 1904 and at least one communication chip 1906. The processor 1904 is physically and electrically coupled to the board 1902. In some implementations the at least one communication chip 1906 is also physically and electrically coupled to the board 1902. In further implementations, the communication chip 1906 is part of the processor 1904.

Depending on its applications, computing device 1900 may include other components that may or may not be physically and electrically coupled to the board 1902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1906 enables wireless communications for the transfer of data to and from the computing device 1900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1900 may include a plurality of communication chips 1906. For instance, a first communication chip 1906 may be dedicated to shorter range wireless communications such as Wi-Fi and Bluetooth and a second communication chip 1906 may be dedicated to longer range wireless communications such as GPS, EDGE, GPRS, CDMA, WiMAX, LTE, Ev-DO, and others.

The processor 1904 of the computing device 1900 includes an integrated circuit die 1910 packaged within the processor 1904. In some implementations of the invention, the integrated circuit die of the processor includes one or more devices 1912, such as tunneling field effect transistors (TFETs) built in accordance with implementations of the invention. The term “processor” may refer to any device or portion of a device that processes electronic data from registers and/or memory to transform that electronic data into other electronic data that may be stored in registers and/or memory.

The communication chip 1906 also includes an integrated circuit die 1920 packaged within the communication chip 1906. In accordance with another implementation of the invention, the integrated circuit die of the communication chip includes one or more devices 1921, such as tunneling field effect transistors (TFETs) built in accordance with implementations of the invention.

In further implementations, another component housed within the computing device 1900 may contain an integrated circuit die that includes one or more devices, such as tunneling field effect transistors (TFETs) built in accordance with implementations of the invention.

In various implementations, the computing device 1900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1900 may be any other electronic device that processes data.

Thus, embodiments of the present invention include tunneling field effect transistors (TFETs) with undoped drain underlap wrap-around regions.

In an embodiment, a tunneling field effect transistor (TFET) includes a homojunction active region formed (e.g., placed, arranged, positioned, disposed) above a substrate. The homojunction active region includes a doped source region, an undoped channel region, a wrapped-around region, and a doped drain region. A gate stack is formed on the undoped channel region, between the source and wrapped-around regions. The gate stack includes a gate dielectric portion and gate electrode portion. The TFET has a length in a first direction and a width in a second direction while the wrapped-around region has a width in the second direction that is greater than a length in the first direction. The length and width of the TFET may be designed to have similar dimensions as a length and width of a metal oxide semiconductor field effect transistor (MOSFET).

In one embodiment, the TFET is a finfet or trigate based device.

In an embodiment, the TFET device further includes symmetric gate spacers each adjacent to the gate electrode. The wrapped-around region may be grown on an exposed portion of the active region and is adjacent to one of the gate spacers of the gate electrode.

In one embodiment, a doped drain region is formed by growing in-situ doped material on an exposed portion of the wrapped-around region.

In one embodiment, the TFET device is a n-type TFET that includes the source region having a p+ dopant and the drain region having a n-type dopant.

In one embodiment, a tunneling field effect transistor (TFET) includes a hetero-junction active region formed above a substrate. The hetero-junction active region includes a doped source region, an undoped channel region, a wrapped-around region, and a doped drain region. A gate electrode and gate dielectric layer are formed on the undoped channel region, between the source and wrapped-around region. A gate stack includes a gate dielectric portion and gate electrode portion.

In one embodiment, the TFET has a length in a first direction and a width in a second direction and the wrapped-around region has a width in the second direction that is greater than a length in the first direction.

In an embodiment, the length and width of the TFET is similar to a length and width of a metal oxide semiconductor field effect transistor (MOSFET). The TFET may be a finfet or trigate based device.

In one embodiment, the TFET device further includes symmetric gate spacers having approximately the same thickness and each adjacent to the gate electrode.

In an embodiment, the wrapped-around region is grown on an exposed portion of the active region and is adjacent to one of the gate spacers of the gate electrode.

A doped drain region is formed by growing in-situ doped material on an exposed portion of the wrapped-around region.

In one embodiment, the TFET device is a n-type TFET that includes the source region having Gallium Antimony (GaSb), the channel region having Indium Arsenide (InAs), and the drain region having InAs.

In one embodiment, a computing device includes memory to store electronic data and a processor coupled to the memory. The processor processes electronic data. The processor includes an integrated circuit die having tunneling field effect transistors (TFETs). At least one TFET includes a hetero-junction active region that is formed above a substrate. The hetero-junction active region includes a doped source region, an undoped channel region, a wrapped-around region, and a doped drain region. A gate electrode and gate dielectric layer are formed on the undoped channel region, between the source and wrapped-around region. A gate stack includes a gate dielectric portion and gate electrode portion.

In one embodiment, the TFET has a length in a first direction and a width in a second direction and the wrapped-around region has a width in the second direction that is greater than a length in the first direction.

In an embodiment, the length and width of the TFET is similar to a length and width of a metal oxide semiconductor field effect transistor (MOSFET). The TFET may be a finfet or trigate based device.

In one embodiment, the TFET device further includes symmetric gate spacers having approximately the same thickness and each adjacent to the gate electrode.

In an embodiment, the wrapped-around region is grown on an exposed portion of the active region and is adjacent to one of the gate spacers of the gate electrode.

A doped drain region is formed by growing in-situ doped material on an exposed portion of the wrapped-around region.

In one embodiment, the TFET device is a n-type TFET that includes the source region having Gallium Antimony (GaSb), the channel region having Indium Arsenide (InAs), and the drain region having InAs.

What is claimed is:

1. A tunneling field effect transistor (TFET), comprising:
a homojunction active region formed above a substrate, the homojunction active region comprises a doped source region, an undoped channel region, a wrapped-around drain underlap region, and a doped drain region; and
a gate electrode and gate dielectric layer formed on an undoped channel region, between the source and wrapped-around region.

2. The TFET of claim 1, wherein the TFET has a length in a first direction and a width in a second direction and the wrapped-around region has a width in the second direction that is greater than a length in the first direction.

3. The TFET of claim 1, wherein the length and width of the TFET is similar to a length and width of a metal oxide semiconductor field effect transistor (MOSFET).

4. The TFET of claim 1, wherein the TFET is a finfet or trigate based device.

5. The TFET of claim 1, wherein the TFET device further comprises:
symmetric gate spacers each adjacent to the gate electrode.

6. The TFET of claim 5, wherein the wrapped-around region is grown on an exposed portion of the active region and is adjacent to one of the gate spacers of the gate electrode.

7. The TFET of claim 1, wherein a doped drain region is formed by growing in-situ doped material on an exposed portion of the wrapped-around region.

8. The TFET of claim 1, wherein the TFET device is a n-type TFET that includes the source region having a p+ dopant and the drain region having a n-type dopant.

9. A tunneling field effect transistor (TFET), comprising:
a hetero-junction active region formed above a substrate, the hetero-junction active region comprises a doped source region, an undoped channel region, a wrapped-around region, and a doped drain region; and
a gate electrode and gate dielectric layer formed on the undoped channel region, between the source and wrapped-around region.

10. The TFET of claim 9, wherein the TFET has a length in a first direction and a width in a second direction and the wrapped-around region has a width in the second direction that is greater than a length in the first direction.

11. The TFET of claim 9, wherein the length and width of the TFET is similar to a length and width of a metal oxide semiconductor field effect transistor (MOSFET).

12. The TFET of claim 9, wherein the TFET is a finfet or trigate based device.

13. The TFET of claim 9, wherein the TFET device further comprises:
symmetric gate spacers having approximately the same thickness and each adjacent to the gate electrode.

14. The TFET of claim 13, wherein the wrapped-around region is grown on an exposed portion of the active region and is adjacent to one of the gate spacers of the gate electrode.

15. The TFET of claim 9, wherein a doped drain region is formed by growing in-situ doped material on an exposed portion of the wrapped-around region.

16. The TFET of claim 9, wherein the TFET device is a n-type TFET that includes the source region having Gallium Antimony (GaSb), the channel region having Indium Arsenide (InAs), and the drain region having InAs.

17. A computing device, comprising:
memory to store electronic data; and
a processor coupled to the memory, the processor to process electronic data, the processor includes an integrated circuit die having a plurality of tunneling field effect transistors (TFETs), at least one TFET comprising:
a hetero-junction active region formed above a substrate, the hetero-junction active region comprises a doped source region, an undoped channel region, a wrapped-around region, and a doped drain region; and
a gate electrode and gate dielectric layer formed on the undoped channel region, between the source and wrapped-around region.

18. The TFET of claim 17, wherein the TFET has a length in a first direction and a width in a second direction and the wrapped-around region has a width in the second direction that is greater than a length in the first direction.

19. The TFET of claim 17, wherein the length and width of the TFET is similar to a length and width of a metal oxide semiconductor field effect transistor (MOSFET).

20. The TFET of claim 17, wherein the TFET is a finfet or trigate based device.

21. The TFET of claim 17, wherein the TFET device further comprises:
symmetric gate spacers having approximately the same thickness and each adjacent to the gate electrode.

22. The TFET of claim 17, wherein the wrapped-around region is grown on an exposed portion of the active region and is adjacent to one of the gate spacers of the gate electrode.

23. The TFET of claim 17, wherein a doped drain region is formed by growing in-situ doped material on an exposed portion of the wrapped-around region.

24. The TFET of claim 17, wherein the TFET device is a n-type TFET that includes the source region having Gallium Antimony (GaSb), the channel region having Indium Arsenide (InAs), and the drain region having InAs.
